(19) United States
(12) Patent Application Publication
(10) Pub. No.: US 2025/0386598 A1
(43) Pub. Date: Dec. 18, 2025

(54) STACKED FETs WITH FLEXIBLE SINGLE DIFFUSION BREAKS

(71) Applicant: International Business Machines Corporation, Armonk, NY (US)

(72) Inventors: Sagarika Mukesh, Albany, NY (US); Ruilong Xie, Niskayuna, NY (US); Alexander Reznicek, Troy, NY (US); Tsung-Sheng Kang, Ballston Lake, NY (US)

(21) Appl. No.: 18/742,800

(22) Filed: Jun. 13, 2024

(51) Int. Cl. H01L 27/02; H01L 27/092; H01L 29/06; H01L 29/423

(52) U.S. Cl. CPC H10D 89/10; H10D 62/115; H10D 62/118; H10D 64/517; H10D 84/85

(57) ABSTRACT

A microelectronic structure includes a stacked FET that includes at least one frontside transistor and at least one backside transistor. A frontside single diffusion break located in a gate region of the at least one frontside transistor. The frontside single diffusion break has a first profile as view from a view perpendicular to a gate direction. A backside single diffusion break is located in a gate region of the at least one backside transistor. The backside single diffusion break has a second profile as view from a view perpendicular to a gate direction and the first profile and the second profile are different.

### BACKGROUND

The present invention generally relates to the field of microelectronics, and more particularly to forming diffusion breaks in stack FETs.

Nanosheet is the lead device architecture in continuing CMOS scaling. However, nanosheet technology has shown issues when scaling down such that as the devices become smaller and closer together, they are interfering with each other. With the number of devices in a stacked FETs it is coming difficult to fabricate diffusion breaks through the upper stacks and lower stacks.

### BRIEF SUMMARY

Additional aspects and/or advantages will be set forth in part in the description which follows and, in part, will be apparent from the description, or may be learned by practice of the invention.

A microelectronic structure includes a stacked FET that includes at least one frontside transistor and at least one backside transistor. A frontside single diffusion break located in a gate region of the at least one frontside transistor. The frontside single diffusion break has a first profile as view from a view perpendicular to a gate direction. A backside single diffusion break is located in a gate region of the at least one backside transistor. The backside single diffusion break has a second profile as view from a view perpendicular to a gate direction and the first profile and the second profile are different.

A microelectronic structure includes a stacked FETs that includes a plurality of frontside transistors and a plurality of backside transistors. A first frontside single diffusion break located in a first gate region of one of the plurality of frontside transistors. A second frontside single diffusion break located in a second gate region of one of the plurality of frontside transistors. The first frontside single diffusion break and the second frontside single diffusion break have a first profile as view from a view perpendicular to a gate direction. A first backside single diffusion break located in a first gate region of one of the plurality of backside transistors. A second backside single diffusion break located in a second gate region of one of the plurality of backside transistors. The first backside single diffusion break 195A and the second backside single diffusion break 195B have a second profile as view from a view perpendicular to a gate direction. The first profile and the second profile are different.

A microelectronic structure that includes a stacked FET, where the stack FET includes at least one frontside transistor and at least one backside transistor. A frontside single diffusion break located in a gate region of the at least one frontside transistor. The frontside single diffusion break has a first profile as view from a view perpendicular to a gate direction. The frontside single diffusion break has a first width as measure perpendicular to the gate direction. A backside single diffusion break located in a gate region of the at least one backside transistor. The backside single diffusion break has a second profile as view from a view perpendicular to a gate. The first profile and the second profile are different. The frontside single diffusion break and the backside single diffusion break are vertically aligned along a common vertical axis. A middle dielectric isolation layer located between the frontside single diffusion break and the backside single diffusion break. The middle dielectric isolation layer as a second as measured perpendicular to the gate direction, where the second width is greater than the first width.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet stacked FET, in accordance with the embodiment of the present invention.

FIG. 2 illustrates a cross section X of the nanosheet stacked FET after initial processing of the stacked FET, in accordance with the embodiment of the present invention.

FIG. 3 illustrates a cross section X of the nanosheet stacked FET after formation of the frontside single diffusion break trenches, in accordance with the embodiment of the present invention.

FIG. 4 illustrates a cross section X of the nanosheet stacked FET after formation of the gate caps and the formation of the frontside single diffusion breaks, in accordance with the embodiment of the present invention.

FIG. 5 illustrates a cross section X of the nanosheet stacked FET after additional frontside processing of the stacked FETs, in accordance with the embodiment of the present invention.

FIG. 6 illustrates a cross section X of the nanosheet stacked FET after flipping the stacked FETs over for backside processing and after initial backside processing of the stacked FETs, in accordance with the embodiment of the present invention.

FIG. 7 illustrates a cross section X of the nanosheet stacked FET after recessing of the placeholders and the formation of the placeholder sacrificial caps, in accordance with the embodiment of the present invention.

FIG. 8 illustrates a cross section X of the nanosheet stacked FET after formation of a lithography layer and formation of backside single diffusion break trenches, in accordance with the embodiment of the present invention.

FIG. 9 illustrates a cross section X of the nanosheet stacked FET after formation of the backside single diffusion breaks, in accordance with the embodiment of the present invention.

FIG. 10 illustrates a cross section X of the nanosheet stacked FET after the removal of the second substrate, in accordance with the embodiment of the present invention.

FIG. 11 illustrates a cross section X of the nanosheet stacked FET after the formation of the backside interlayer dielectric layer, in accordance with the embodiment of the present invention.

FIG. 12 illustrates a cross section X of the nanosheet stacked FET after the removal of the placeholder sacrificial caps and the placeholders, in accordance with the embodiment of the present invention.

FIG. 13 illustrates a cross section X of the nanosheet stacked FET after the formation of backside contacts and the backside-power-distribution-network, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards stacked field-effect-transistors (stacked FETs), specifically the present invention is directed towards formation of single diffusion breaks in a stacked FET. The present invention will illustrate a plurality of different arrangements of the single diffusion breaks. Separate diffusion breaks are formed in the frontside of the stacked FET and the backside of the stacked FET. The profile of a frontside single diffusion break is different than the profile of a backside single diffusion break when viewed from a cross-section along the stacked FET where the cross-section is perpendicular to the gate direction. The frontside single diffusion break and the backside single diffusion break can be aligned along a common vertical axis or be offset from each other. The present invention only illustrates two frontside single diffusion breaks and two backside single diffusion breaks, but this is for illustrative purposes only. A plurality of frontside single diffusion breaks (one, two, three, or more) can be present in the stacked FET device (i.e., when more than one transistor is present) and a plurality of backside single diffusion breaks (one, two, three, or more) can be present in the stacked FET device. The number of frontside single diffusion breaks can be less than, equal to, or greater than the number of backside single diffusion breaks. Therefore, any number of combinations of aligned or offset frontside single diffusion breaks and backside single diffusion breaks can be present in the stacked FET device.

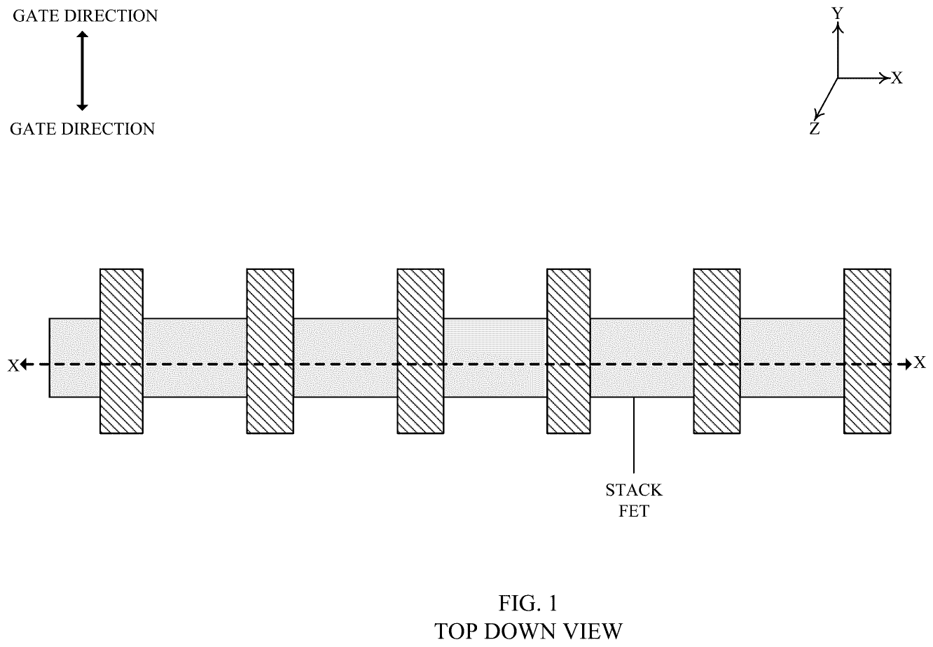

FIG. 1 illustrates a top-down view of a plurality of nanosheet stacked FETs, in accordance with the embodiment of the present invention. The cross-section X extends horizontally through the stacked nanosheet FET transistors. Cross-section X is perpendicular to the gate direction.

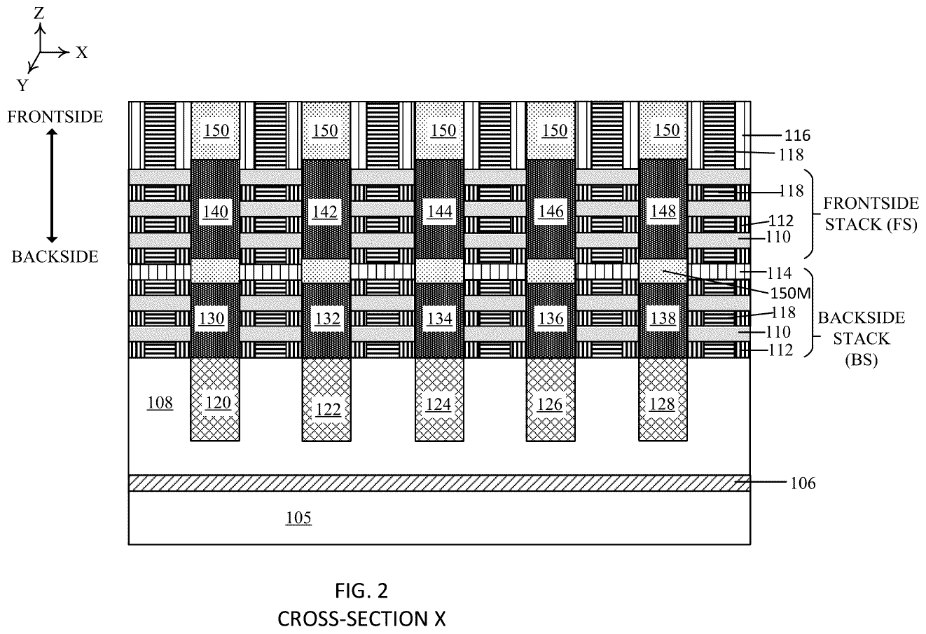

Referring now to FIG. 2, a structure is shown during an intermediate step of a method of fabricating stacked nano devices, such as, a stacked nanosheet transistors structure after initial processing of the frontside of the stacked FET, according to an embodiment of the invention.

FIG. 2 illustrates the nano stack of the nanosheet transistors that includes a first substrate 105, an etch stop 106, a second substrate 108, placeholders 120, 122, 124, 126, 128, a backside stack (BS), a frontside stack (FS), a middle dielectric isolation layer 114, interlayer dielectric layer 150, a gate spacer 116, gate 118, lower source/drain 130, 132, 134, 136, 138 (herein after also referred to as backside source/drains), upper source/drains 140, 142, 144, 146, 148 (herein after also referred to as frontside source/drains), and a separating dielectric layer 150M.

The first substrate 105 and the second substrate 108 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of the first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor first substrate 105 and the second substrate 108 may be doped, undoped or contain doped regions and undoped regions therein.

The frontside stack FS and the backside stack BS each includes a plurality of channel layers 110, an inner spacer 112, and the gate 118. The plurality of channel layers 115 can be comprised of, for example, Si. The frontside stack FS and the backside stack BS are separated by the middle dielectric isolation layer 114. Gate 118 is located around the channel layers 110 of both the frontside stack FS and the backside stack BS. Gate 118 is further located between segments of gate spacer 116. Gate 118 can be comprised of, for example, a gate dielectric liner, such as high-k dielectric like HfO₂, ZrO₂, HfLaOₓ, etc., and work function layers, such as TiN, TiAlC, TiC, etc., and conductive metal fills, like W.

The separating dielectric layer 150M is located on top of each of the backside source/drains 130, 132, 134, 136, 138 and each of the frontside source/drains 140, 142, 144, 146, 148 is located on top of the separating dielectric layer 150M. The frontside interlayer dielectric layer 150 is located on top of each of the frontside source/drains 140, 142, 144, 146, 148.

The plurality of backside source/drains (lower source/drains) 130, 132, 134, 136, 138 and the plurality of frontside source/drains (the upper source/drains) 140, 142, 144, 146, 148 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

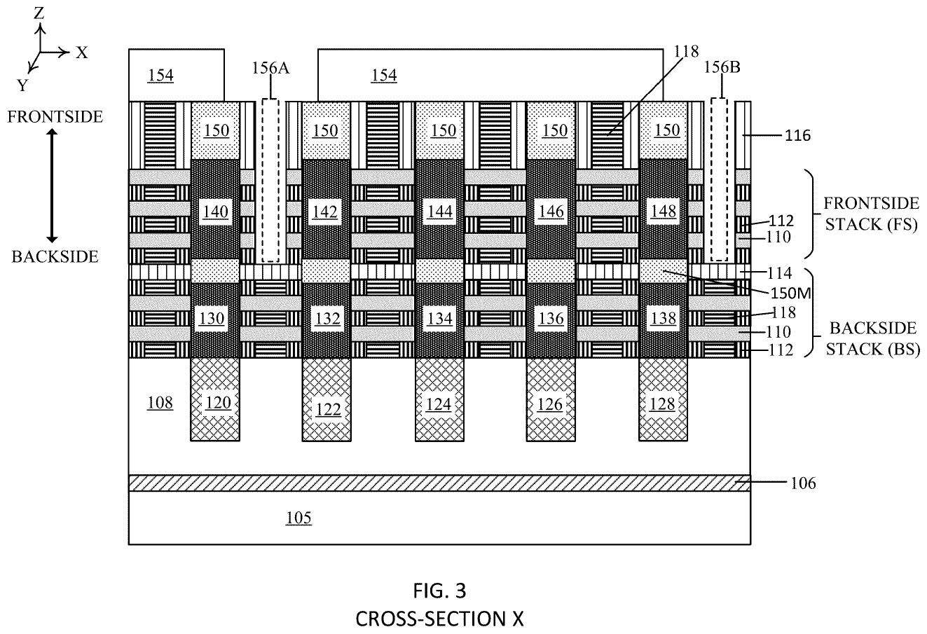

FIG. 3 illustrates the processing stage after formation of the frontside single diffusion break trenches 156A, 156B. A lithography layer 154 is formed on top of the stacked FET. Lithography layer 154 is patterned to expose select locations for the formation of the frontside single diffusion breaks. The patterning of the lithography layer 154 exposes a top surface of gate 118 located on top of the frontside stack FS. Gate 118 and the channel layers 110 of the frontside stack are etched to form the frontside single diffusion break trenches 156A, 156B. The frontside single diffusion break trenches 156A, 156B extends from a top surface of the middle dielectric isolation layer 114 to the top surface of the gate spacer 116. The frontside single diffusion break trenches 156A, 156B does not extend downwards through the middle dielectric isolation layer 114.

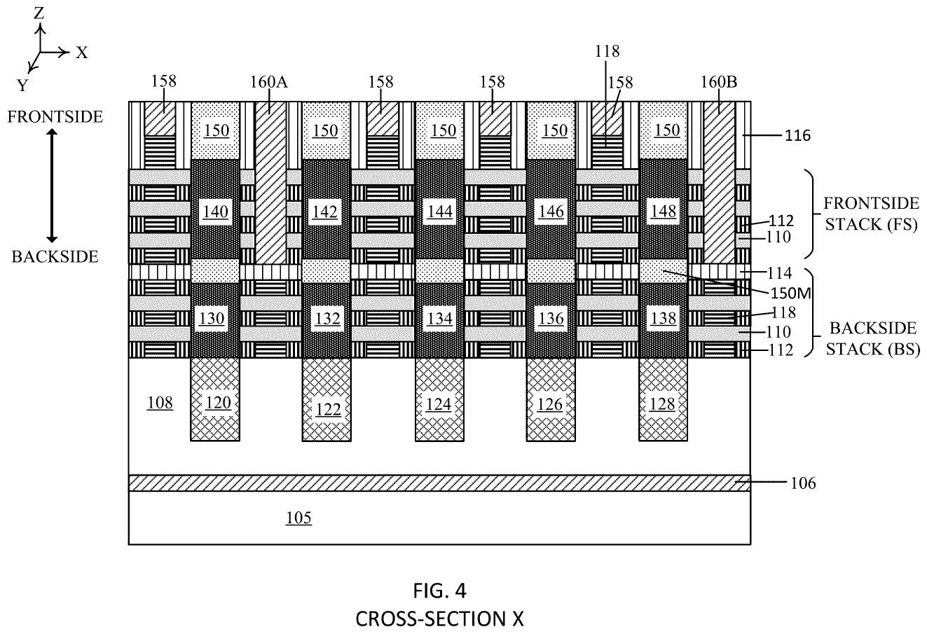

FIG. 4 illustrates the processing stage after formation of the gate caps 158 and the formation of the frontside single diffusion breaks 160A, 160B. Lithography layer 154 is removed. An optional processing step of creating a recess (not shown) located above gate 118 and between segments of the gate spacer 116 can be achieved by pulling down/recessing the gate 118. The frontside single diffusion break trenches 156A, 156B and the recesses (not shown) that are located above gates 118 are filled with a dielectric material. Gate cap 158 is located on top of gates 118 and the gate cap 158 is located between vertical segments of the gate spacer 116. Frontside single diffusion breaks 160A, 160B are located where the frontside single diffusion break trenches 156A, 156B were formed. Frontside single diffusion breaks 160A, 160B are located adjacent to gate spacer 116, portions of channel layers 110, and the inner spacer 112. The bottom surface of each of the frontside single diffusion breaks 160A, 160B is in contact with a top surface or a frontside surface of the middle dielectric isolation layer 114. The frontside single diffusion breaks 160A, 160B have a vertical shaft profile having a constant width, as viewed along the illustrated cross section (i.e., across multiple stacked FETs and perpendicular to the gate direction). Each of the frontside single diffusion breaks 160A, 160B has a relatively constant width as each of the frontside single diffusion breaks 160A, 160B extends up from the middle dielectric isolation layer 114 to the top surface or frontside surface of each of the frontside single diffusion breaks 160A, 160B.

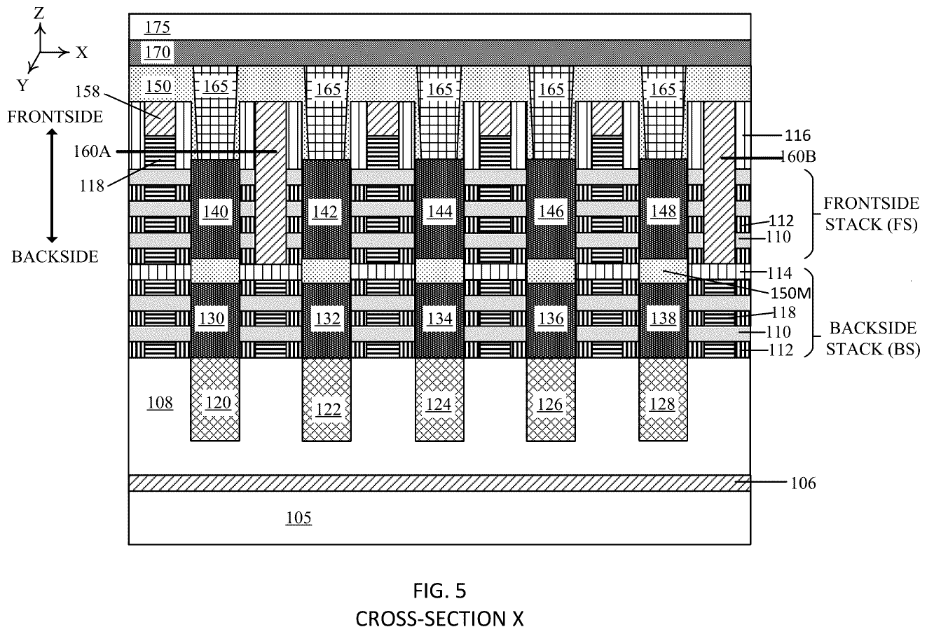

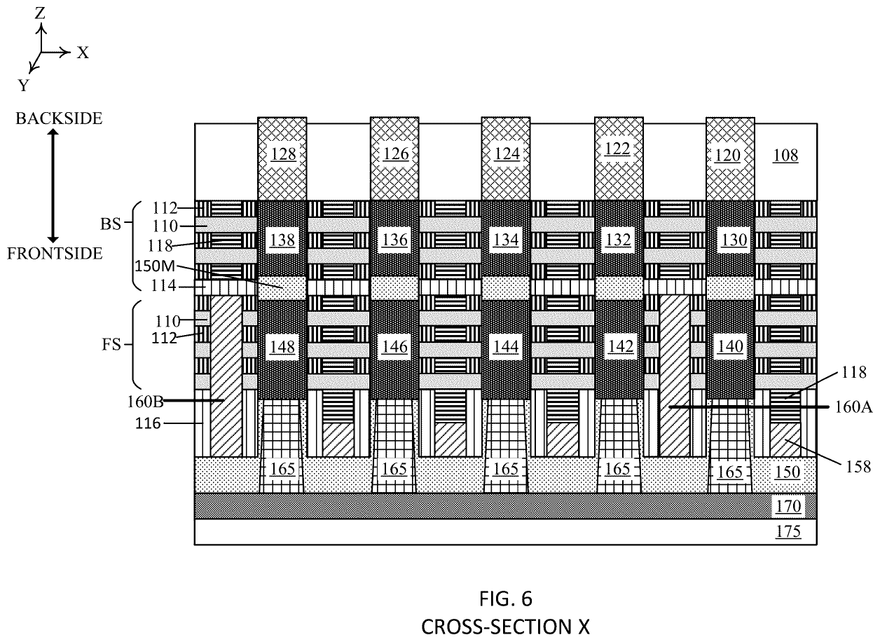

FIG. 5 illustrates the processing stage after additional frontside processing of the stacked FETs. The height of the frontside interlayer dielectric layer 150 is increased to extend above the gate caps 158 and the frontside single diffusion breaks 160A, 160B. A plurality of trenches (not shown) are formed in the frontside interlayer dielectric layer 150, where each of the trenches exposes a top surface of a frontside source/drain 140, 142, 144, 146, 148 or a top surface of gate 118. The trenches are filled with a conductive metal to form frontside source/drain contacts 165 and frontside gate contacts (not shown). A back-end-of-the-line (BEOL) layer 170 is located on top of the frontside interlayer dielectric layer 150, frontside source/drain contact 165, and frontside gate contacts (not shown). The BEOL layer 170 is an interconnect that can be comprised of multiple layers, multiple metal lines, and connecting vias that make the necessary connections to the underlying stacked FETs or other devices. Carrier wafer 175 is located on top of the BEOL layer 170. Carrier wafer 175 allows for the stacked FETs device to be flipped over for backside processing. FIGS. 2-5 illustrate the frontside processing of the stacked FETs and FIGS. 6-13 illustrate the backside processing of the stacked FETs.

FIG. 6 illustrates the processing stage after flipping the stacked FETs over for backside processing and after initial backside processing of the stacked FETs. The stacked FETs are flipped over for backside processing. The first substrate 105 and the etch stop 106 are removed which exposes the second substrate 108. The second substrate 108 is recessed to expose a top surface of the placeholders 120, 122, 124, 126, 128.

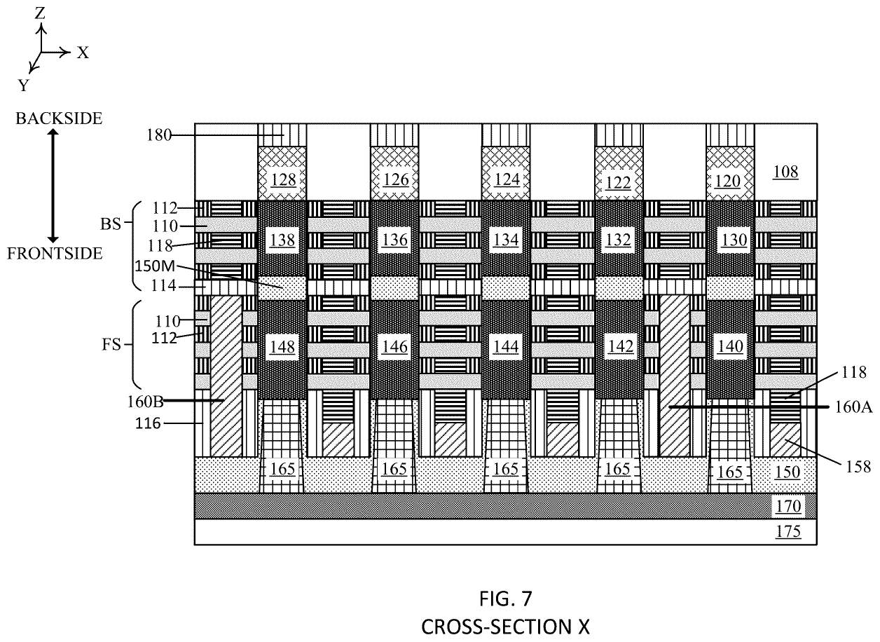

FIG. 7 illustrates the processing stage after recessing of the placeholders 120, 122, 124, 126, 128 and the formation of the placeholder sacrificial caps 180. The placeholders 120, 122, 124, 126, 128 are recessed to form trenches (not shown) located above the placeholders 120, 122, 124, 126, 128 and between sections of the second substrate 108. These trenches are filled with sacrificial material to form the placeholder sacrificial caps 180.

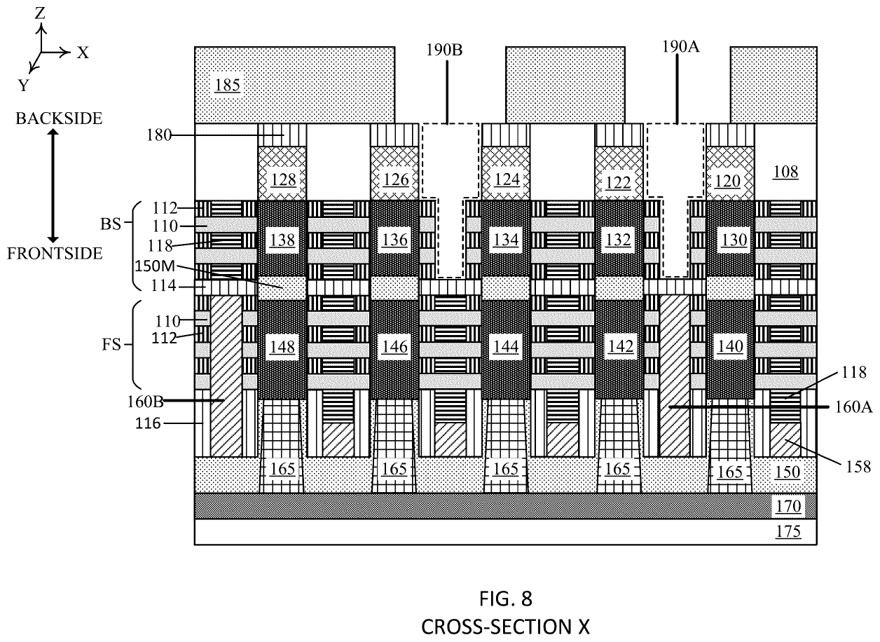

FIG. 8 illustrates the processing stage after formation of a lithography layer 185 and formation of backside single diffusion break trenches 190A, 190B. A lithography layer 185 is located on top of the second substrate 108 and on top of the placeholder sacrificial caps 180. Lithography layer 185 is patterned to expose different portions of the second substrate 108 where the second diffusion break trenches 190A, 190B will be located. The exposed portions of the second substrate 108 are located between different placeholders 120, 122, 124, 126, 128. A head section of the backside single diffusion break trenches 190A, 190B is formed by removing portions of the second substrate 108. A shaft section of the backside single diffusion break trenches 190A, 190B is formed by removing portions of the channel layer 110, and gate 118 of the backside stack BS. The shaft section/portion of the backside single diffusion break trenches 190A, 190B does not extend through the middle dielectric isolation layer 114. Backside single diffusion break trenches 190A could be vertically aligned with the frontside single diffusion breaks 160A, such that the shaft section of the backside diffusion break trench 190A is aligned along a common vertical axis of the frontside diffusion break 160A. Additionally, or alternatively, the backside single diffusion break trenches 190B can be offset from the frontside single diffusion breaks 160B, such that the backside single diffusion break trenches 190B are not vertically aligned along a common access with the frontside single diffusion breaks 160B.

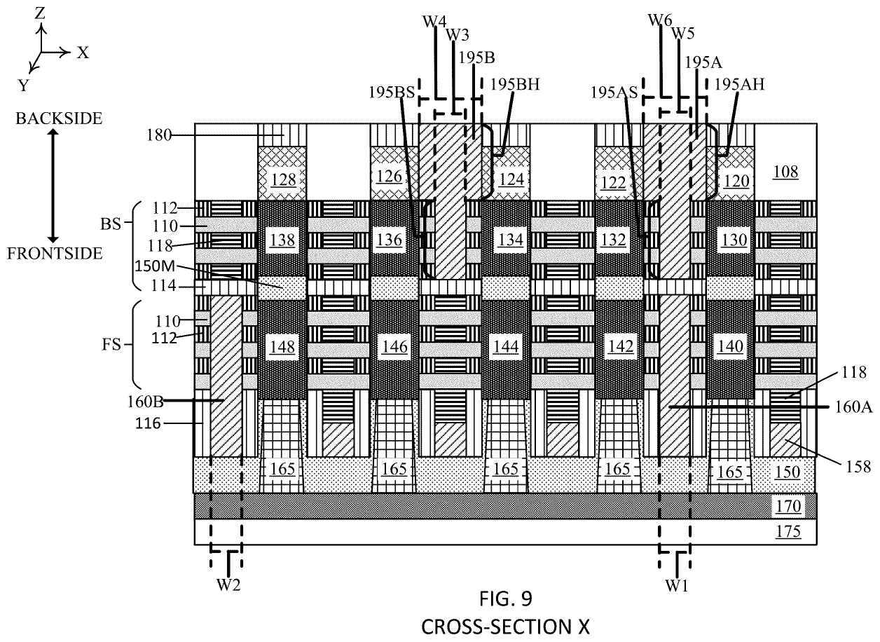

FIG. 9 illustrates the processing stage after formation of the backside single diffusion breaks 195A, 195B. The backside single diffusion break trenches 190A, 190B are filled with a dielectric material to form the backside single diffusion breaks 195A, 195B. Each of the backside single diffusion breaks 195A, 195B includes a shaft section 195BS, 195AS and a head section 195BH, 195AH. The frontside single diffusion breaks 160A, 160B are each comprised of a shaft section that have a width W1, W2, respectively. The widths W1 and W2 are relatively constant along the vertical length of each of the frontside single diffusion breaks 160A, 160B. The widths W5 and W3 of the shaft section 195AS, 195BS of the backside single diffusion breaks 195A, 195B, respectively, are different from the widths W6 and W4 of the head sections 195AH, 195BH of the backside single diffusion breaks 195A, 195B. Widths W5 and W3 of shaft section 195AS, 195BS of the backside single diffusion breaks 195A, 195B is substantially equal to the widths W1 and W2 of the frontside single diffusion breaks 160A, 160B. The widths W6 and W4 of the head sections 195AH, 195BH of the backside single diffusion breaks 195A, 195B is larger than the widths W5, W3 of the shaft sections 195AS, 195BS of the backside single diffusion breaks 195A, 195B, respectively. Excess dielectric material and the lithography layer 185 are removed by, for example, chemical mechanical processing (CMP).

The backside single diffusion breaks 195A, 195B have a T-shape/bolt profile that is comprised of a head section 195AH, 195BH and a shaft section 195AS, 195BS as referenced from a view perpendicular to the gate direction across the stacked FETs. Therefore, the backside single diffusion breaks 195A, 195B have a first profile. The frontside single diffusion breaks 160A, 160B has a second profile, such that, the profile of the frontside single diffusion breaks 160A, 160B is a vertical shaft as referenced from a view perpendicular to the gate direction across the stacked FETs. The first profile of the backside single diffusion breaks 195A, 195B is different the second profile of the frontside single diffusion breaks 160A, 160B.

FIG. 9 illustrates that the shaft section 195AS of the backside diffusion break 195A is vertical aligned with the frontside single diffusion break 160A. The middle dielectric isolation layer 114 is located between the backside single diffusion break 195A and the frontside single diffusion break 160A. The width of the middle dielectric isolation layer 114 is greater than the width W5 of the shaft section 195AS of the backside single diffusion break 195A and the width of the middle dielectric isolation layer 114 is greater than the width W1 of the frontside single diffusion break 160A. The backside single diffusion break 195B is offset from the frontside single diffusion break 160B, meaning that these diffusion breaks are not vertical aligned. The Figures only illustrate two backside single diffusion breaks 195A, 195B and two frontside single diffusion breaks 160A, 160B, but this is not meant to be limiting. The number of frontside or backside diffusion breaks can be less than, equal to, or greater than the number of breaks shown in the Figures. The number of aligned and offset combinations (as illustrated) of the frontside and backside single diffusion breaks is not meant to be limiting. It is well within the skill level of one of ordinary skill in the art to utilize the present disclosure to realize that any type of combination of aligned or offset frontside and backside single diffusion breaks can be achieved by practicing the present invention.

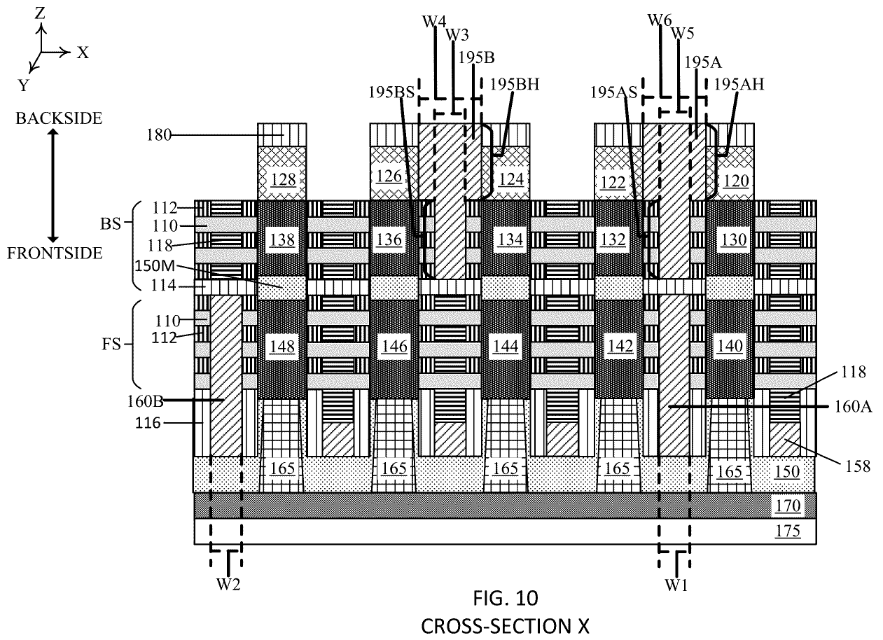

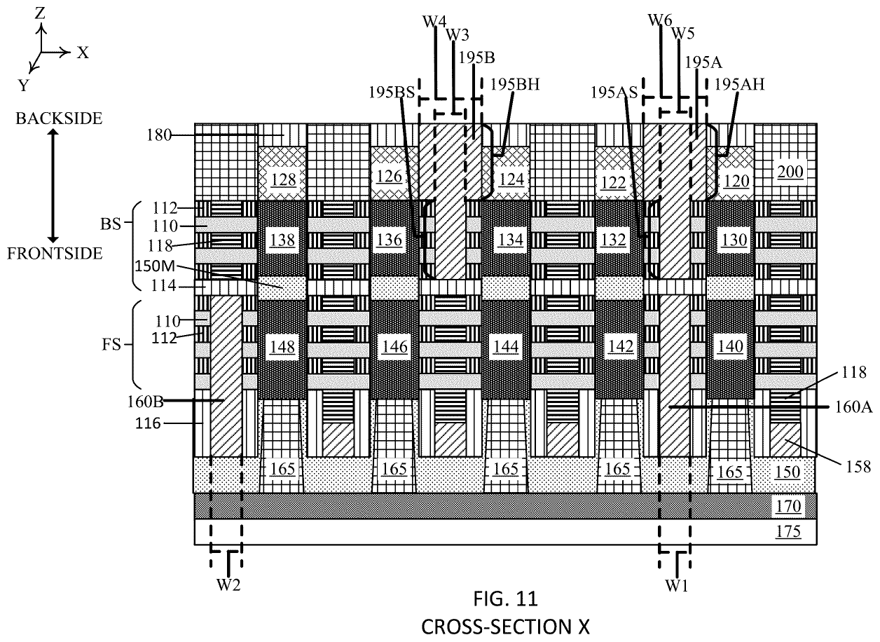

FIG. 10 illustrates the processing stage after the removal of the second substrate 108. The second substrate 108 is removed causing the exposure of the sidewalls of the placeholders 120, 122, 124, 126, 128. FIG. 11 illustrates the processing stage after the formation of the backside interlayer dielectric layer 200. The backside interlayer dielectric layer 200 is formed in the location of the removed second substrate 108. The backside interlayer dielectric layer 200 is in contact with the placeholders 120, 122, 124, 126, 128, but the backside interlayer dielectric layer 200 is not in contact with the sidewalls of the head section 195AH, 195BH of the backside single diffusion breaks 195A, 195B when view along a cross section perpendicular to the gate direction (i.e., the illustrated cross section X).

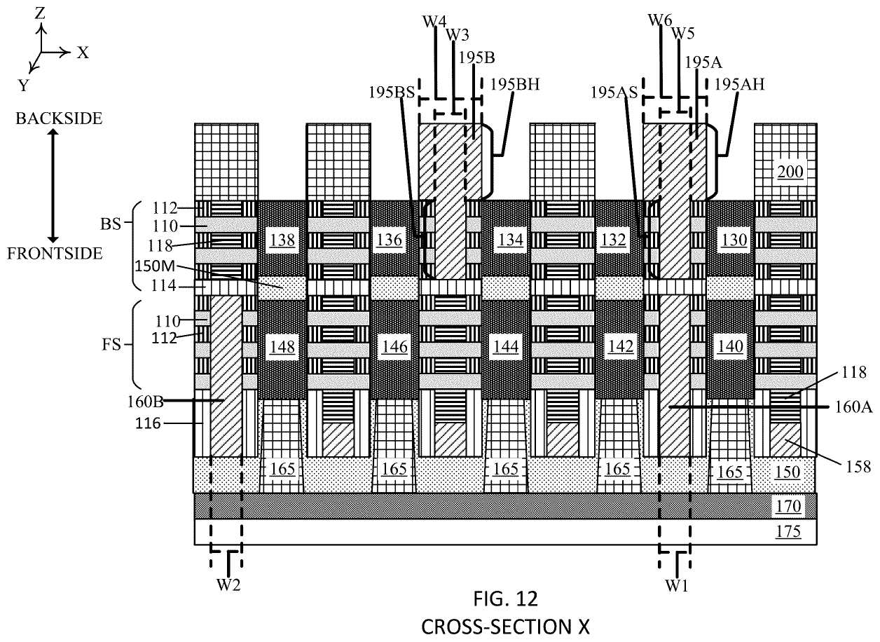

FIG. 12 illustrates the processing stage after the removal of the placeholder sacrificial caps 180 and the placeholders 120, 122, 124, 126, 128. The placeholder sacrificial caps 180 are selectively removed to expose the placeholders 120, 122, 124, 126, 128. Placeholders 120, 122, 124, 126, 128 are selectively removed. The removal of the placeholders 120, 122, 124, 126, 128 exposes the backside surfaces of the backside source/drains 130, 132, 134, 136, 138. Furthermore, the sidewalls of the backside single diffusion break 195A, 195B are exposed by removal of the placeholders 120, 122, 124, 126, 128, as illustrated in FIGS. 12. The removal of the placeholders 120, 122, 124, 126, 128 causes the formation of trenches located between sections of the backside interlayer dielectric layer 200 and/or backside single diffusion break 195A, 195B.

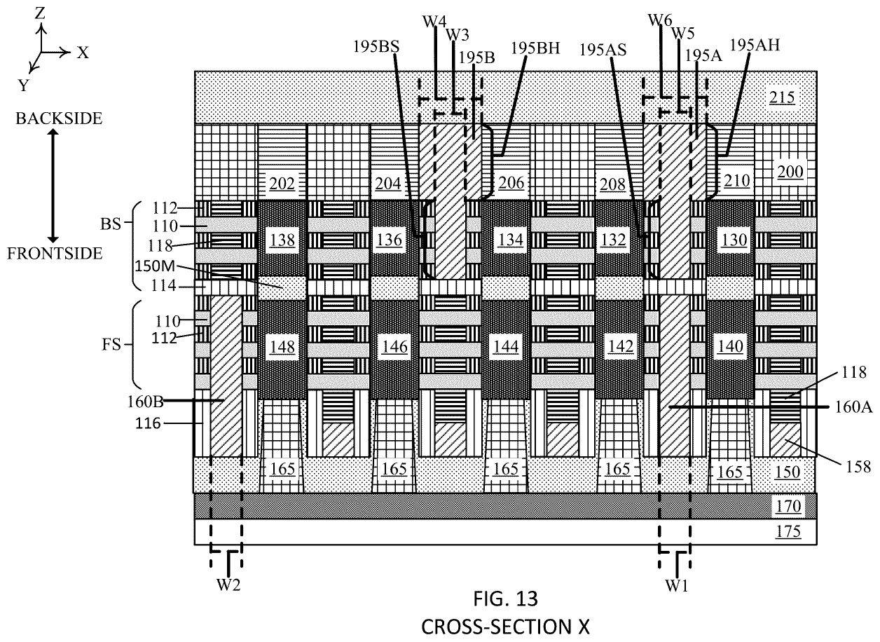

FIG. 13 illustrates the processing stage after the formation of backside contacts 202, 204, 206, 208, 210 and the backside-power-distribution-network (or backside interconnect) 215. The trenches located above the backside source/drains 130, 132, 134, 136, 138 are filled with a conductive metal to form the backside contacts 202, 204, 206, 208, 210. The backside contacts 202, 204, 206, 208, 210 can be in contact with a sidewall of the backside interlayer dielectric layer 200 and/or the sidewall of the head section 195AH, 195BH of the backside single diffusion breaks 195A, 195B. The backside contacts 202, 204, 206, 208, 210 are not in contact with shaft section 195AS, 195BS of the backside single diffusion breaks 195A, 195B. A backside interconnect or backside-power-distribution-network (BSPDN) 215 is formed on top of the backside contacts 202, 204, 206, 208, 210, the backside interlayer dielectric layer 200, and a backside surface of the head section 195AH, 195BH of the backside single diffusion breaks 195A, 195B.

A microelectronic structure includes a stacked FET that includes at least one frontside transistor (at least one frontside stack FS and source/drains 140, 142) and at least one backside transistor (at least one backside stack BS and source/drains 130, 132). A frontside single diffusion break 160A, 160B located in a gate region of the at least one frontside transistor. The frontside single diffusion break 160A, 160B has a first profile (i.e., a vertical shaft as illustrated in FIG. 13) as view from a view perpendicular to a gate direction (cross-section X). A backside single diffusion break 195A, 195B is located in a gate region of the at least one backside transistor. The backside single diffusion break 195A, 195B has a second profile (the T-shape/bolt profile as illustrated in FIG. 13) as view from a view perpendicular to a gate direction (cross-section X) and the first profile (shaft profile) and the second profile (T-shape/bolt profile) are different.

The frontside single diffusion break 160A and the backside single diffusion break 195A are vertically aligned along a common vertical axis (see, for example, FIG. 13). A middle dielectric isolation layer 114 is located between the frontside single diffusion break 160A and the backside single diffusion break 195A.

The frontside single diffusion break 160B and the backside single diffusion break 195B are offset from each other.

A width of the frontside single diffusion break 160A, 160B is constant along its vertical length.

A width of the backside single diffusion break 195A, 19B varies along its vertical length. The backside single diffusion break 195A, 195B has a head section 195AH, 195BH and a shaft section 195AS, 195BS. The width of the backside single diffusion break 195A, 195B varies between the head section 195AH, 195BH and the shaft section 195AS, 195BS. The head section 195AH, 195BH of the backside single diffusion break 195A, 195 has a first width (widths W6 and W4 as illustrated in FIG. 13) and the shaft section 195AS, 195BS of the backside single diffusion break 195A, 195B has a second width (widths W5 and W3 as illustrated in FIG. 13). The first width (W6, W4) is greater than the second width (W5, W3). The frontside single diffusion break 160A, 160B has a third width (widths W1 and W2 as illustrated in FIG. 13) that is constant along its vertical length. The second width (W5, W3) of the shaft section 195AS, 195BS of the backside single diffusion break 195A, 195B is substantially equal to the third width (W1, W2) of the frontside single diffusion break 160A, 160B.

A microelectronic structure includes a stacked FETs that includes a plurality of frontside transistors (a plurality of frontside stacks FS and plurality of frontside source/drains 140, 142, 144, 146, 148) and a plurality of backside transistors (a plurality of backside stacks BS and plurality of backside source/drains 130, 132, 134, 136, 138). A first frontside single diffusion break 160A located in a first gate region of one of the plurality of frontside transistors. A second frontside single diffusion break 160B located in a second gate region of one of the plurality of frontside transistors. The first frontside single diffusion break 160A and the second frontside single diffusion break 160B have a first profile (e.g. a vertical shaft) as view from a view perpendicular to a gate direction (illustrated cross-section X). A first backside single diffusion break 195A located in a first gate region of one of the plurality of backside transistors. A second backside single diffusion break 195B located in a second gate region of one of the plurality of backside transistors. The first backside single diffusion break 195A and the second backside single diffusion break 195B have a second profile (e.g., T-shaped/bolt shape) as view from a view perpendicular to a gate direction (illustrated cross-section X). The first profile (e.g., the shaft profile) and the second profile (e.g., the T-shape/bolt profile) are different.

The first frontside single diffusion break 160A and the first backside single diffusion break 195A are vertically aligned along a common first vertical axis (as illustrated in FIG. 13). A middle dielectric isolation layer 114 is located between the first frontside single diffusion break 160A and the first backside single diffusion break 195A.

The second frontside single diffusion break 160B and the second backside single diffusion break 195B are vertically aligned along a common second vertical axis. The figures illustrate only that the first frontside single diffusion break 160A and the first backside single diffusion break 195A are vertically aligned along a common vertical axis. It is well within the skill level of one of ordinary skill in the art to vertically aligned the second frontside single diffusion break 160B and the second backside single diffusion break 195B along a common vertical axis.

The second frontside single diffusion break 160B and the second backside single diffusion break 195B are offset from each other.

A width of the first backside single diffusion break 195A varies along its vertical length, and a width of the second backside single diffusion break 195B varies along its vertical length. The first backside single diffusion break 195A and the second backside diffusion break 195B each has a head section 195AH, 195BH and a shaft section 195AS, 195BS. The width of each of the first backside single diffusion break 195A and the second backside diffusion break 195B varies between the head section 195AH, 195BH and the shaft section 195AS, 195BS, respectively.

The head section 195AH of the first backside single diffusion break 195A has a first width (W6 as indicated in FIG. 13) and the shaft section 195AS of the first backside single diffusion break 195A has a second width (W5 as indicated in FIG. 13). The first width (W6) is greater than the second width (W5).

The first frontside single diffusion break 160A has a third width (W1 as indicated in FIG. 13) that is constant along its vertical length. The second width (W5) of the shaft section 195AS of the first backside single diffusion break 195A is substantially equal to the third width (W1) of the first frontside single diffusion break 160A.

A microelectronic structure that includes a stacked FET, where the stack FET includes at least one frontside transistor (at least one frontside stack FS and source/drains 140, 142) and at least one backside transistor (at least one backside stack BS and source/drains 130, 132). A frontside single diffusion break 160A located in a gate region of the at least one frontside transistor. The frontside single diffusion break 160A has a first profile (e.g., a vertical shaft as illustrated in FIG. 13) as view from a view perpendicular to a gate direction (the illustrated cross-section X). The frontside single diffusion break 160A has a first width (W1 as indicated in FIG. 13) as measure perpendicular to the gate direction. A backside single diffusion break 195A located in a gate region of the at least one backside transistor. The backside single diffusion break 195A has a second profile (e.g., a T-shape/bolt profile) as view from a view perpendicular to a gate direction (i.e., the illustrated cross-section X). The first profile (e.g., the shaft profile) and the second profile (e.g., the T-shape/bolt profile) are different. The frontside single diffusion break 160A and the backside single diffusion break 195B are vertically aligned along a common vertical axis. A middle dielectric isolation layer 114 located between the frontside single diffusion break 160A and the backside single diffusion break 195A. The middle dielectric isolation layer 114 as a second width (FIG. 13 does not explicitly indicated a width) as measured perpendicular to the gate direction (i.e., the illustrated cross-section X), where the second width is greater than the first width (W1) (FIG. 13 clearly illustrates that the width of the middle dielectric isolation layer 114 is wider than the width W1 of the frontside single diffusion break 160A).

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a stacked FET that includes at least one frontside transistor and at least one backside transistor;
a frontside single diffusion break is located in a gate region of the at least one frontside transistor, wherein the frontside single diffusion break has a first profile as view from a view perpendicular to a gate direction; and
a backside single diffusion break is located in a gate region of the at least one backside transistor, wherein the backside single diffusion break has a second profile as view from a view perpendicular to the gate direction, wherein the first profile and the second profile are different.

2. The microelectronic structure of claim 1, wherein the frontside single diffusion break and the backside single diffusion break are vertically aligned along a common vertical axis.

3. The microelectronic structure of claim 2, further comprising:
a middle dielectric isolation layer located between the frontside single diffusion break and the backside single diffusion break.

4. The microelectronic structure of claim 1, wherein the frontside single diffusion break and the backside single diffusion break are offset from each other.

5. The microelectronic structure of claim 1, wherein a width of the frontside single diffusion break is constant along its vertical length.

6. The microelectronic structure of claim 1, wherein a width of the backside single diffusion break varies along its vertical length.

7. The microelectronic structure of claim 6, wherein the backside single diffusion break has a head section and a shaft section, wherein the width of the backside single diffusion break varies between the head section and the shaft section.

8. The microelectronic structure of claim 7, wherein the head section of the backside single diffusion break has a first width and the shaft section of the backside single diffusion break has a second width, wherein the first width is greater than the second width.

9. The microelectronic structure of claim 8, wherein the frontside single diffusion break has a third width that is constant along its vertical length.

10. The microelectronic structure of claim 9, wherein the second width of the shaft section of the backside single diffusion break is substantially equal to the third width of the frontside single diffusion break.

11. A microelectronic structure comprising:
a stacked FETs that includes a plurality of frontside transistors and a plurality of backside transistors;
a first frontside single diffusion break located in a first gate region of one of the plurality of frontside transistors;
a second frontside single diffusion break located in a second gate region of one of the plurality of frontside transistors, wherein the first frontside single diffusion break and the second frontside single diffusion break have a first profile as view from a view perpendicular to a gate direction;
a first backside single diffusion break located in a first gate region of one of the plurality of backside transistors; and
a second backside single diffusion break located in a second gate region of one of the plurality of backside transistors, wherein the first backside single diffusion break and the second backside single diffusion break have a second profile as view from a view perpendicular to the gate direction, wherein the first profile and the second profile are different.

12. The microelectronic structure of claim 11, wherein the first frontside single diffusion break and the first backside single diffusion break are vertically aligned along a common first vertical axis.

13. The microelectronic structure of claim 12, further comprising:
a middle dielectric isolation layer located between the first frontside single diffusion break and the first backside single diffusion break.

14. The microelectronic structure of claim 13, wherein the second frontside single diffusion break and the second backside single diffusion break are vertically aligned along a common second vertical axis.

15. The microelectronic structure of claim 13, wherein the second frontside single diffusion break and the second backside single diffusion break are offset from each other.

16. The microelectronic structure of claim 11, wherein a width of the first backside single diffusion break varies along its vertical length, and wherein a width of the second backside single diffusion break varies along its vertical length.

17. The microelectronic structure of claim 16, wherein the first backside single diffusion break and the second backside diffusion break each has a head section and a shaft section, wherein the width of each of the first backside single diffusion break and the second backside diffusion break varies between the head section and the shaft section, respectively.

18. The microelectronic structure of claim 17, wherein the head section of the first backside single diffusion break has a first width and the shaft section of the first backside single diffusion break has a second width, wherein the first width is greater than the second width.

19. The microelectronic structure of claim 18, wherein the first frontside single diffusion break has a third width that is constant along its vertical length, wherein the second width of the shaft section of the first backside single diffusion break is substantially equal to the third width of the first frontside single diffusion break.

20. A microelectronic structure comprising:
a stacked FET that includes at least one frontside transistor and at least one backside transistor;
a frontside single diffusion break located in a gate region of the at least one frontside transistor, wherein the frontside single diffusion break has a first profile as view from a view perpendicular to a gate direction, wherein the frontside single diffusion break has a first width as measure perpendicular to the gate direction;
a backside single diffusion break located in a gate region of the at least one backside transistor, wherein the backside single diffusion break has a second profile as view from a view perpendicular to the gate direction, wherein the first profile and the second profile are different, wherein the frontside single diffusion break and the backside single diffusion break are vertically aligned along a common vertical axis;
a middle dielectric isolation layer located between the frontside single diffusion break and the backside single diffusion break, wherein the middle dielectric isolation layer as a second width as measured perpendicular to the gate direction, wherein the second width is greater than the first width.
